(19) United States
(12) Patent Application Publication
(10) Pub. No.: US 2025/0087557 A1
(43) Pub. Date: Mar. 13, 2025

(54) SANDWICHED MULTI-LAYER STRUCTURE FOR COOLING HIGH POWER ELECTRONICS

(71) Applicant: Tesla, Inc., Austin, TX (US)

(72) Inventors: Aydin Nabovati, San Francisco, CA (US); Mitchell Heschke, Los Altos, CA (US); Zheng Gao, Sunnyvale, CA (US); Vijaykumar Krithivasan, Mountain View, CA (US); Mohamed Haitham Helmy Nasr, Sunnyvale, CA (US)

(21) Appl. No.: 18/580,580

(22) PCT Filed: Aug. 16, 2022
(86) PCT No.: PCT/US2022/040509

§ 371 Date: Jan. 18, 2024

Related U.S. Application Data
(60) Provisional application No. 63/234,602, filed on Aug. 18, 2021.

(51) Int. Cl. H01L 23/473; H01L 25/065

(52) U.S. Cl. CPC H01L 23/473; H01L 25/0655; H01L 2225/06589

(57) ABSTRACT

The systems, methods, and devices disclosed herein relate to sandwiched multi-layer structures for cooling electronics. In some embodiments, a computing assembly can include a first cooling system, a first electronics layer, a second cooling system, and a second electronics layer. The first cooling system can be disposed on top of and can be in thermal communication with the first electronics layer, the first electronics layer can be disposed on top of and can be in thermal communication with the second cooling system, and the second cooling system can be disposed on top of and can be in thermal communication with the second electronics layer. In some embodiments, at least one layer can use system on wafer packaging.

### CROSS-REFERENCE TO RELATED APPLICATION

This application claims the benefit of U.S. Provisional Application No. 63/234,602, filed Aug. 18, 2021, titled “A SANDWICHED MULTI-LAYER STRUCTURE FOR COOLING HIGH POWER ELECTRONICS,” the disclosure of which is incorporated herein by reference in its entirety and for all purposes.

### BACKGROUND

### Technical Field

This disclosure relates to electronic assemblies, and more specifically to cooling electronic assemblies.

### Description of Related Technology

High performance computing systems are important for many applications. However, conventional computing system designs can face significant cooling challenges and can use space inefficiently, which can lead to reduced performance, increased physical space requirements, and so forth.

High performance computing applications such as artificial intelligence, machine learning, and data mining can benefit from high computing density. For example, locating computing dies near one another can reduce the physical space occupied for a particular computing capacity, can improve communication bandwidth and latency between dies, and so forth. Packaging techniques such as System on Wafer (SoW) have made it feasible to build very high-density computing systems with little area in between dies. Such packaging methods can provide significant improvements in computing density but also present significant challenges. When dies are located very close together, there can be large power consumption in a relatively small area, which can present significant challenges for cooling the dies and other nearby components.

As the performance of electronic systems increases and the sizes of electronic components shrink, significant heat generation can occur in smaller and smaller volumes. Furthermore, in applications such as high-density neural network training systems and other large-scale distributed computing applications, locating computing nodes physically close to each other can increase performance. While some conventional systems can work with cooling solutions that are one-sided (e.g., that cool only from the top or only from the bottom) and that have a footprint much larger than the electronic device to be cooled, such an approach may not work in some high-performance, high-density systems. For example, a typical central processing unit (CPU) cooler in a desktop computer or server may take up an area tens or even hundreds of times that of the CPU die in order to provide adequate cooling, but there is insufficient available area for such a solution when dies are placed adjacent to one another with little space in between.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a computing assembly including: a first cooling system; a first electronics layer having a first surface and a second surface, wherein the first surface is in thermal communication with the first cooling system; a second cooling system in thermal communication with the second surface of the first electronics layer; and a second electronics layer having a third surface and a fourth surface, wherein the third surface is in thermal communication with the second cooling system.

In some aspects, the techniques described herein relate to a computing assembly, wherein the first cooling system is disposed on top of the first electronics layer, wherein the first electronics layer is disposed on top of the second cooling system, and wherein the second cooling system is disposed on top of the second electronics layer.

In some aspects, the techniques described herein relate to a computing assembly, further including: a third cooling system; and a third electronics layer having a fifth surface and sixth surface, wherein the fifth surface is in thermal communication with the third cooling system, wherein and the fourth surface is in thermal communication with the third cooling system.

In some aspects, the techniques described herein relate to a computing assembly, wherein the first electronics layer is in electrical communication with the second electronics layer.

In some aspects, the techniques described herein relate to a computing assembly, wherein the first electronics layer includes a system on wafer layer.

In some aspects, the techniques described herein relate to a computing assembly, wherein the first electronics layer includes an array of integrated circuit dies, and wherein the second electronics layer includes an array of power delivery modules.

In some aspects, the techniques described herein relate to a computing assembly, wherein each power delivery module of the array of power delivery modules includes a voltage regulating module.

In some aspects, the techniques described herein relate to a computing assembly, wherein a number of integrated circuit dies in the first electronics layer is equal to a number of power delivery modules in the second electronics layer, and wherein each integrated circuit die is in electrical communication with only one power delivery module.

In some aspects, the techniques described herein relate to a computing assembly, wherein power is delivered vertically from the second electronics layer to the first electronics layer, and wherein the integrated circuit dies of the array of integrated circuit dies are in electronic communication with each other in a plane that is orthogonal to the power delivery.

In some aspects, the techniques described herein relate to a computing assembly, wherein a type of the first cooling system and a type of the second cooling system include one or more of a cold plate, a heatsink, and a liquid cooling block.

In some aspects, the techniques described herein relate to a computing assembly, wherein the type of the first cooling system is the same as the type of the second cooling system.

In some aspects, the techniques described herein relate to a computing assembly, wherein the type of the first cooling system is different from the type of the second cooling system.

In some aspects, the techniques described herein relate to a computing assembly, wherein the first cooling system includes a first liquid cooling block and the second cooling system includes a second liquid cooling block.

In some aspects, the techniques described herein relate to a computing assembly, wherein the first liquid cooling block is configured to receive a first coolant, and wherein the second liquid cooling block is configured to receive a second coolant.

In some aspects, the techniques described herein relate to a computing assembly, wherein the first coolant and the second coolant include one or more of water, propylene glycol, ethylene glycol, or any combination thereof.

In some aspects, the techniques described herein relate to a computing assembly, wherein the first coolant is the same as the second coolant.

In some aspects, the techniques described herein relate to a computing assembly, wherein the first coolant is different from the second coolant.

In some aspects, the techniques described herein relate to a method for cooling an electronic assembly including: mounting a first cooling layer on top of and in thermal communication with a first electronics layer; mounting a first electronics layer on top of and in thermal communication with a second cooling system; and mounting a second cooling system on top of and in thermal communication with a second electronics layer.

In some aspects, the techniques described herein relate to a method, further including: outputting heat vertically from the first electronics layer to the first cooling system; outputting heat vertically from the first electronics layer to the second cooling system; and outputting heat vertically from the second electronics layer to the second cooling system.

In some aspects, the techniques described herein relate to a method, further including: providing power vertically from the second electronics layer to the first electronics layer.

In some aspects, the techniques described herein relate to a computing assembly including: a first cooling system; a first electronics layer in thermal communication with the first cooling system; a second cooling system in thermal communication with the first electronics layer; a second electronics layer in thermal communication with the second cooling system; a third cooling system in thermal communication with the second electronics layer; and a third electronics layer in thermal communication with the third cooling system, wherein the first electronics layer includes a processing electronics layer, wherein the second electronics layer includes a power delivery layer, and wherein the third electronics layer includes a control electronics layer.

### BRIEF DESCRIPTION OF THE DRAWINGS

This disclosure is described herein with reference to drawings of certain embodiments, which are intended to illustrate, but not to limit, the present disclosure. It is to be understood that the accompanying drawings, which are incorporated into and constitute a part of this specification, are for the purpose of illustrating concepts disclosed herein and may not be to scale.

FIG. 1 is a schematic diagram which shows an example of an array of integrated circuit dies and power, cooling and control signals running perpendicular to computing loads and signaling.

FIG. 2 is a block diagram which shows an example of a conventional prior art one-sided cooling system with a single cooling system on top of an electronics layer.

FIG. 3 is a block diagram which shows an example of a prior art double-sided cooling system with a cooling system between two electronics layers according to one embodiment.

FIG. 4 is a block diagram which shows an example embodiment of a vertical cooling solution with two cooling systems and two electronics layers according to one embodiment.

FIG. 5 is a block diagram which shows another example embodiment of a vertical cooling solution with two cooling systems and three electronics layers according to one embodiment.

FIG. 6 is a block diagram which shows another example embodiment of a vertical cooling solution with three cooling systems and three electronics layers according to one embodiment.

FIG. 7A is a perspective exploded view of a computing assembly comprising a system on wafer layer according to one embodiment.

FIG. 7B is an exploded block diagram of a computing assembly showing cooling inlets and outlets according to one embodiment.

FIG. 7C show an assembled block diagram of the system shown in FIG. 7A comprising a system on wafer layer according to some embodiments.

### DETAILED DESCRIPTION OF THE PREFERRED EMBODIMENT

The following description of certain embodiments presents various descriptions of specific embodiments. However, the innovations described herein may be embodied in a multitude of different ways, for example, as defined and covered by the claims. In this description, reference is made to the drawings where like reference numerals may indicate identical or functionally similar elements. It will be understood that elements illustrated in the figures are not necessarily drawn to scale. Moreover, it will be understood that certain embodiments may include more elements than illustrated in a drawing and/or a subset of the elements illustrated in a drawing. Further, some embodiments may incorporate any suitable combination of features from two or more drawings.

When computing dies are very close together, it may be advantageous to configure a system such that some components are vertically arranged. For example, power delivery, control circuitry, and so forth may be located below the dies, and power and cooling can be delivered vertically while signals and computing loads travel horizontally from die to die in an array. In some cases, an array of dies and associated power, control, and cooling hardware can be assembled into a computing assembly, and computing assemblies may be placed near (e.g., next to) each other with little space in between. In some embodiments, computing assemblies may be configured with high-speed communications interfaces to enable computing assemblies to communicate with each other. Thus, while in a conventional computing system where density is not a major concern or where only one or a few CPU dies may be present, horizontal power delivery and/or cooling solutions with large horizontal areas may be viable. However, in a high-density setting, such as when using SoW or other high density packaging techniques, there may not be horizontal space available for routing power, clock signals, and so forth horizontally. The limited horizontal space can be used for enabling communication between nodes in an array.

The present disclosure describes a cooling architecture in which multiple levels of single- and double-sided cooling solutions can be used between high power electronic components. The cooling solutions described herein can be used to create a highly dense cooling structure that can cool multiple electronic systems within a compact structure. Such structures can help increase computational density. In some embodiments, electronic components can be placed on either side of a cooling component, which can help to increase density and reduce packaging volume.

In some embodiments, the structure can include a heterogeneous combination of cooling solutions. For example, a cooling structure can include a combination of liquid-cooled components, air-cooled components, immersion cooling, and so forth. In some embodiments, different coolants can be used. For example, one component may be liquid-cooled with water while another component may be liquid-cooled with an oil, propylene glycol, and so forth. The particular cooling components, coolants, etc., can be based on the cooling needs of various components. For example, a voltage regulator module may be able to withstand temperatures that substantially exceed the thermal limits of a computing die, and thus may, in some embodiments, be cooled by cooling components with less cooling capacity than the cooling components used for cooling a die.

In some embodiments, the cooling structures described herein can be used for cooling System on Wafer (SoW) systems, which may include many processors or processor dies physically located very near each other on a single board. These cooling structures for SoW systems may include a sandwiched structure that can provide efficient double-sided cooling to the high-power SoW layer. In some embodiments, the cooling structure can include one or more components which provide mechanical support for the SOW layer and can enhance the mechanical integrity of the SoW layer.

In some embodiments, the cooling structures described herein can enable orthogonal flow of heat and information. For example, power and heat can flow from bottom to top and/or top to bottom, while information and computational workloads can flow in the horizontal plane orthogonal to that of the heat and power.

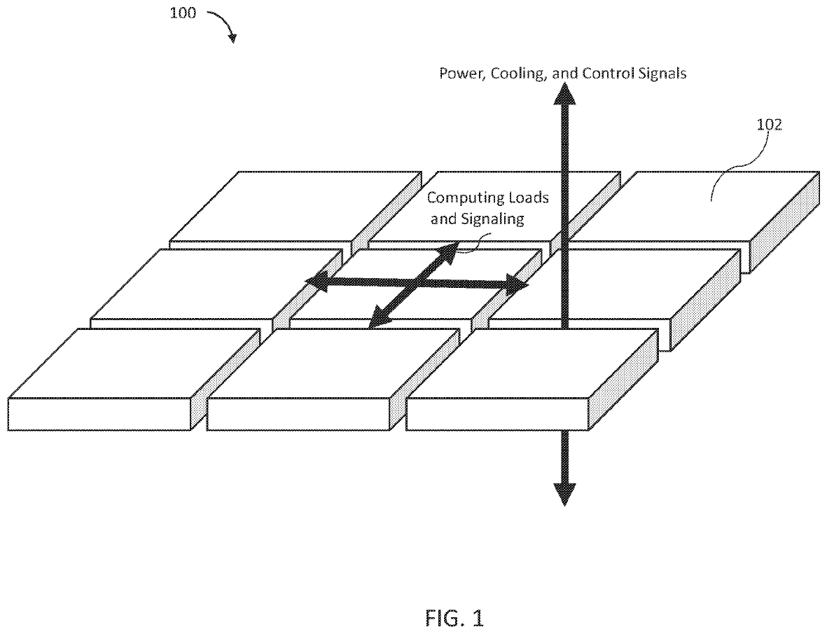

FIG. 1 shows an example of an array 100. The array 100 can comprise a plurality of integrated circuit (IC) dies 102. The dies 102 can receive power and/or control signals vertically. The dies 102 can be cooled vertically. The dies 102 can communicate with each other via horizontal communication links. For example, a SoW layer can include one or more routing layers, for example 4, 5, 6, 8, or 10 routing layers. The routing layers can provide signal connectivity between IC dies 102 within the SoW layer and/or to external components.

In some embodiments, an SoW layer can include an array of IC dies positioned on a wafer. In some embodiments, the IC dies can include a sensor die, a memory die, an application specific integrated circuit (ASIC) die, a central processing unit (CPU) die, a graphical processing unit (GPU) die, a field programmable gate array (FPGA) die, and/or a microelectromechanical systems (MEMS) die. In some embodiments, the IC dies can communicate with each other within the SoW through a redistribution layer (RDL) formed therein. The RDL layer and/or other electrical connections with the SoW can beneficially provide, for example, a relatively low communication latency between the IC dies, a relatively high bandwidth density, and/or a relatively low power distribution network (PDN) impedance.

It should also be realized that each array 100 may include connections for communicating between a plurality of SoW arrays within a larger system. For example, the array 100 may be part of a system containing 4, 8, 12, 16 or more SoW arrays, each one communicating with each other through connectors located in the same or similar plane as the SoW array.

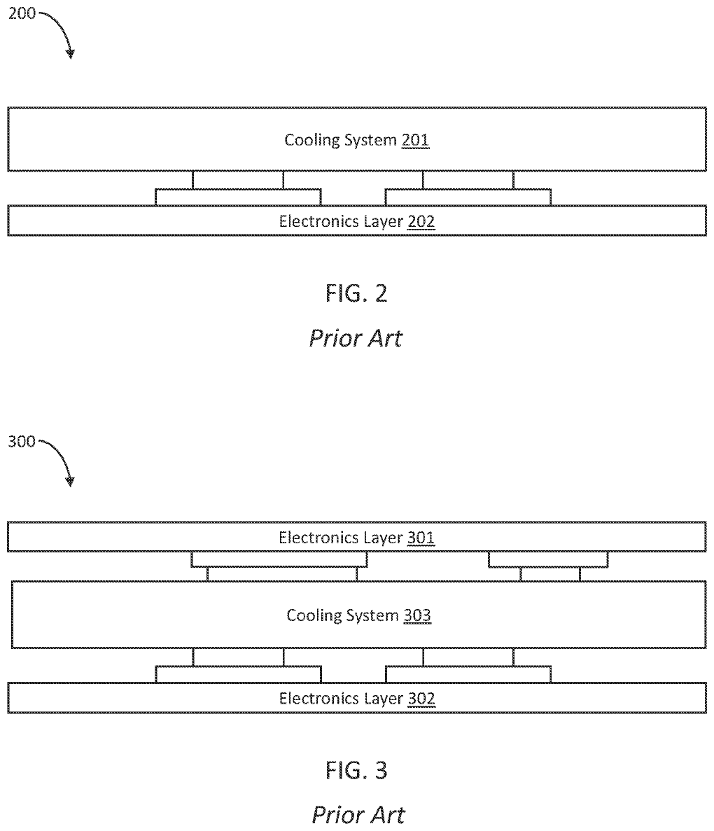

FIG. 2 shows an example of a conventional prior art one-sided cooling system 200. A cooling system 201 can be mounted on top of electronics layer 202. A thermal interface material (TIM) can be disposed between the cooling system 201 and the electronics layer 202 to facilitate heat transfer. The TIM may be, for example, a thermal pad, thermal adhesive, thermal pad, and so forth. The electronics layer 202 may comprise, for example, a printed circuit board (PCB) with various integrated circuits or other components affixed (e.g., soldered) to the PCB. All or some of the ICs and/or other components may be in thermal contact with the cooling system 201. The cooling system 201 may be any type of cooling solution, such as a heatsink, cold plate, vapor chamber, liquid cooling block, and so forth. The cooling solution may be active or passive. In some cases, a fan may be used to aid in dissipating heat away from the electronics layer 202.

FIG. 3 is an example of prior art showing a two-sided cooling system 300. As shown in FIG. 3, density can be improved by placing electronics in thermal communication with both sides (e.g., the top and bottom) of a cooling solution. As shown in FIG. 3, electronics layer 301 and electronics layer 302 are disposed on opposite sides of cooling system 303 and are in thermal communication with cooling system 303. Provided the cooling system 303 has sufficient thermal capacity to cool both electronics layer 301 and electronics layer 302, such a configuration may offer space savings by avoiding the use of a second cooling solution.

As discussed briefly above, high density computing presents challenges for cooling, power delivery, signaling, and so forth. Density can be increased by stacking components vertically. Effectively cooling a vertical stack of components can present several challenges. For example, some components may output more or less heat than other components, some components may be able to operate at higher or lower temperatures than other components, and so forth. As described herein, some embodiments of a cooling solution can account for differences in cooling requirements for different components to efficiently cool vertically stacked components.

In some embodiments, a high-density computing system can comprise an SoW assembly that includes multiple cooling systems disposed under, on top of, intertwined with, or between electronics layers for efficient, double-sided cooling of heat-generating electronics. Such an architecture may not only provide efficient cooling to the SoW layer and/or other electronics layers but can also provide a high level of mechanical support for enhancing the mechanical integrity of the SoW layer, which can be fragile.

SoW assemblies can include an SoW layer and cooling systems that are integrated or sandwiched into the SoW assembly. The SoW assembly can include an array of IC dies. The IC dies of the SoW assembly can generate significant heat during operation. The cooling systems can dissipate heat generated in the SoW assembly by the IC dies and/or other electronic components within the SoW assembly

Some embodiments herein relate to SoW assemblies that include integrated cooling systems or structures for providing efficient thermal management of the heat generating components within the SoW assembly. In some embodiments, the SoW assembly can include multiple distinct cooling systems, for example three cooling systems, although more or fewer cooling systems are also contemplated.

The systems and methods described herein can be used in processing systems having a high compute density and can dissipate heat generated by the processing system. In some embodiments, a processing system can execute trillions of operations per second in certain applications. In some embodiments, the processing system can be used in and/or specifically configured for high performance computing and computation-intensive applications, such as neural network processing, machine learning, artificial intelligence, and so forth. In some embodiments, the processing system can implement redundancy. For example, the processing system may include redundant dies, redundant power supplies, redundant storage, or other failover mechanisms that can be used to minimize disruptions in operation. In some embodiments, the processing system can be used in an autopilot system of a vehicle (e.g., an automobile), to implement other autonomous vehicle functionality, to implement Advanced Driving Assistance System (ADAS) functionality, or the like.

In some embodiments, alternating layers of coolers and electronic components can be stacked to form a vertical structure. In some embodiments, a thermal interface material may be disposed between electronic layers and coolers to facilitate heat transfer from electronic components to the coolers. As discussed above, the TIM can be a thermal paste, thermal adhesive, thermal pad, or other suitable material. In some embodiments, components can be cooled from one side (e.g., from top or bottom) or from both sides (e.g., top and bottom). In some embodiments, a cooler can have components on one side (e.g., top or bottom) or on both sides of the cooler. In some embodiments, an electronics layer can be adjacent to another electronics layer without an intervening cooling system. In some embodiments, a cooling system can be adjacent to another cooling system without an intervening electronics layer.

In some embodiments, all the coolers in a stack can be the same, but this need not be the case. For example, electronic components that benefit from greater cooling can be cooled by coolers with greater heat dissipation capabilities (e.g., liquid cooling), while some other components that can operate at higher temperatures and/or that generate less heat can be cooled by components with less cooling capacity such as a cold plate, heatsink, or vapor chamber. In some embodiments, one or more electronics layers can be cooled using immersion cooling, for example immersion in a hydrocarbon- or fluorocarbon-based fluid.

In some embodiments, different coolants may be used in different liquid cooling blocks within a stack. For example, a liquid cooling block can use water, propylene glycol, ethylene glycol, mineral oils, refrigerants, isopropyl alcohol, ethanol, methanol, glycerin, and/or mixtures of the above, for example a mix of 1:1 propylene glycol and water or ethylene glycol and water, or another ratio as may be desirable for cooling. In some embodiments, a cooling liquid may include some amount of biocidal and/or anti-corrosive compounds to prevent micro-organism growth and/or to prevent corrosion of cooling components.

In some embodiments, if a system includes multiple liquid coolers, they may share some common components such as reservoirs, radiators, and/or pumps. In some embodiments, different liquid coolers may not share any common components.

Stacked structures can present particular challenges for cooling. For example, inlets and outlets for liquid cooling can be difficult to access, and may have limited configuration possibilities due to the lack of space at the sides of a cooling solution to route pipes, hoses, and so forth, especially when stacked structures are placed next to one another. Thus, preferably inlets and outlets are configured to provide vertical coolant delivery and return. In some embodiments, the size (i.e., horizontal dimensions) of layers in a vertical stack can vary from layer to layer. In some embodiments, the horizontal sizing of layers can be limited due to space occupied by cooling lines for other layers, the space occupied by electrical connectors for connecting one computing assembly to a neighboring computing assembly, and so forth.

In some embodiments, a cooling solution can include one or more fans. For example, a cooling solution can include one or more fans disposed at the top and/or bottom of the vertical stack. In some embodiments, one or more fans may be disposed within a vertical stack. In some embodiments, the vertical stack may be installed in a housing or chassis (e g., a computer enclosure, rack-mounted enclosure, etc.), which may include one or more fans.

As mentioned briefly above, different cooling solutions may be provided for different layers, including the type of cooler, whether cooling is provided from one side or both sides, and so forth. The type of cooler and/or coolant can be selected based at least in part on the components, the computational loads, the relative locations of components within the vertical stack, the locations of components within an enclosure or chassis, neighboring components (e.g., neighboring computing assemblies, storage, controllers, etc.), and so forth. Some components, such as voltage regulator modules (VRMs) may be able to operate at relatively high temperatures (e.g., up to about 125° C., up to about 110° C., up to about 90° C., etc., or any temperature between these temperatures, or even more depending on the characteristics of the components), while other components (e.g., IC dies) may have relatively low maximum operating temperatures or may otherwise be cooled more aggressively, for example to operate more efficiently and consume less power. For example, an IC die may have a maximum operating temperature of about 105° C., about 95° C., about 85° C., or more or less depending on the characteristics of the IC die (e.g., a die prepared according to one manufacturing process may be able to operate in a different temperature range than a die manufactured using another process). Similarly, other components in the stack, such as control circuitry, may have maximum operating temperatures or other constraints on the operating temperature.

In some embodiments, the cooling systems described herein may comprise a material with a relatively high coefficient of thermal expansion (CTE). For example, the cooling system can comprise copper (Cu) and/or Aluminum (Al). In some embodiments, the cooling system can comprise a material that has a CTE in a range of from about 10 ppm/° C. to about 20 ppm/° C. For example, the cooling system can comprise copper with a CTE of about 17 ppm/° C. In some embodiments, an SoW layer can comprise a silicon (Si) wafer. In some embodiments, the SoW layer can comprise a material having a CTE in a range of from about 1 ppm/° C. to about 10 ppm/° C. For example, silicon can have a CTE of about 2.6 ppm/° C. In some embodiments, the CTE of the cooling system can be from about two to about seven times greater than the CTE of the SoW layer.

At least in part because of thermal stresses that can arise due to the differing thermal expansion of components within a stack, components may be prone to premature failure. Thus, it can be important to ensure that components are maintained within temperature ranges that avoid excessive stresses due to non-uniform thermal expansion. In some embodiments, careful alignment of components within the stack can help to alleviate some effects of thermal stresses. For example, a cooler can be centered with respect to the IC dies so that any stresses on a die are uniformly (e.g., substantially uniformly) applied.

In order to obtain desirable heat dissipation and/or to mitigate potential thermal stress issues, it can be beneficial to align the SoW layer and the cooling systems with a relatively high precision. For example, it can be beneficial to align the SoW layer and the cooling system such that a reference point (e.g., a center point) of the SoW layer aligns with a reference point (e.g., a center point) of the cooling system. In some embodiments, there may be a plurality of alignment markers that can be used to align the SoW layer and the cooling system.

In some embodiments, different electronic components within the vertical stack may include temperature sensors. For example, an IC die can have one or more temperature sensors, power delivery hardware such as VRMs can have one or more temperature sensors, control circuitry can have one or more temperature sensors, and so forth. In some embodiments, temperature data from multiple sensors may be aggregated together at various levels. In some embodiments, the aggregated data may be used for adjusting cooling, such as changing a fan speed, increasing or decreasing a coolant flow rate, and the like. In some embodiments, all the temperature sensors on a particular IC die can be aggregated. In some embodiments, all the temperature sensors in all the IC dies in an SoW layer can be aggregated. In some embodiments, all temperature sensors on power delivery components can be aggregated. In some embodiments, all temperature sensors in a computing assembly can be aggregated. In some embodiments, all temperature sensors in a larger cabinet or structure comprising a plurality of computing assemblies can be aggregated.

Desired aggregation levels can depend upon the specific cooling implementation. For example, a lower level of aggregation may be desirable when different cooling systems, different computing assemblies, etc. can be cooled independently, while a greater level of aggregation may be desirable when cooling is controlled at a higher level, for example per-computing assembly or per-cabinet. In some embodiments, even if only high-level cooling control is available, lower-level aggregation may still be desirable. For example, in some embodiments, the IC dies may be particularly sensitive to temperature while other components may be relatively resilient. Thus, it may be advantageous to monitor IC die temperatures without aggregating them with other temperature data and/or by giving IC die temperatures greater weight than temperatures of other components.

In some embodiments, cooling can be adjusted by adjusting the opening of a mechanical valve, adjusting the speed of a mechanical fan, and so forth. Such adjustments can take a significant amount of time, during which IC dies and other components may continue to rise in temperature. Thus, in some embodiments, a system can be configured to predict future thermal demands, for example based on computing loads, ambient temperature, and so forth, and cooling can be adjusted based on the predicted thermal demands, which may help to avoid overheating of components.

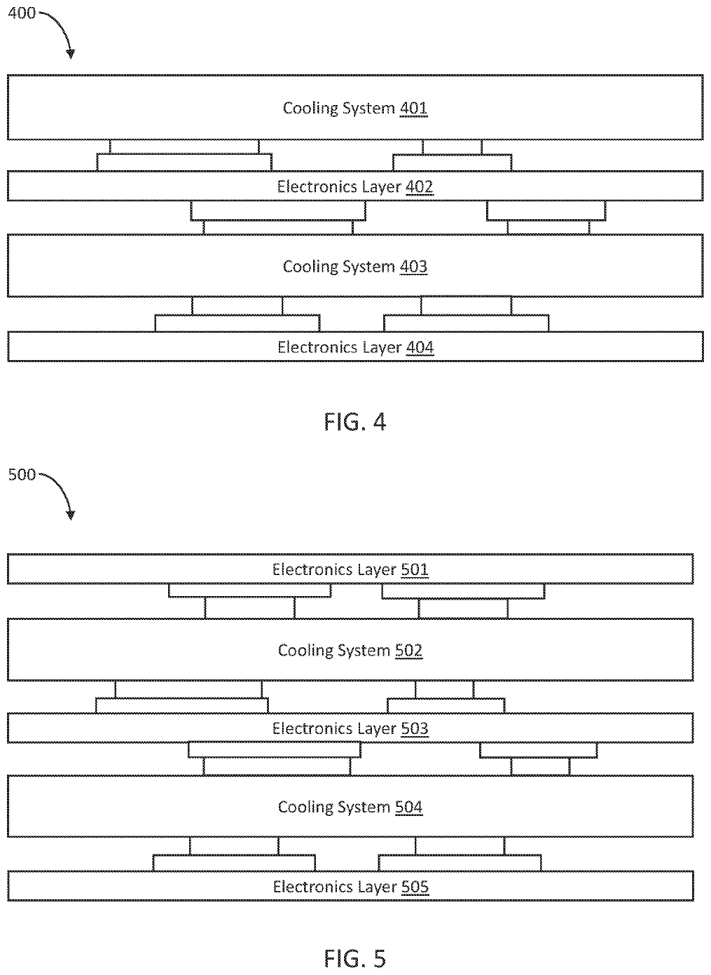

FIG. 4 shows an example vertical cooling solution 400 according to some embodiments. As shown in FIG. 4, a cooling system 401 can be disposed on top of a double-sided electronics layer 402. The double-sided electronics layer can be disposed on top of a cooling system 403. The cooling system 403 can be disposed on top of an electronics layer 404. As shown in FIG. 4, the cooling system 401 can be single-sided. That is, there is an electronics layer 402 in contact with the bottom surface of the cooling system 401, but no electronics layer is in contact with the top surface of the cooling system 401. In contrast, the cooling system 403 can be double-sided. That is, cooling system 403 is thermally coupled to the electronics layer 402 on the top side and to the electronics layer 404 on the bottom side of the cooling system 403. Electronics components can also be single-sided or dual-sided. For example, electronics layer 402 is double-sided, with electronic components disposed on both sides of a substrate (e.g., PCB, wafer, etc.). Electronics layer 404 is single-sided, with electronic components disposed only on the top side of the substrate.

FIG. 5 shows another example vertical cooling solution 500 according to some embodiments. FIG. 5 is substantially similar to FIG. 4 but with an additional electronics layer 501. Electronics layer 501 is a single-sided electronics layer disposed on top of double-sided cooling system 502. Cooling system 502 is disposed on top of double-sided electronics layer 503 Electronics layer 503 is disposed on top of double-sided cooling system 504, which is disposed on top of single-sided electronics layer 505. The layers shown in FIG. 5 can be in direct thermal communication with adjacent layers. The layers shown in FIG. 5 can be in indirect thermal communication with non-adjacent layers.

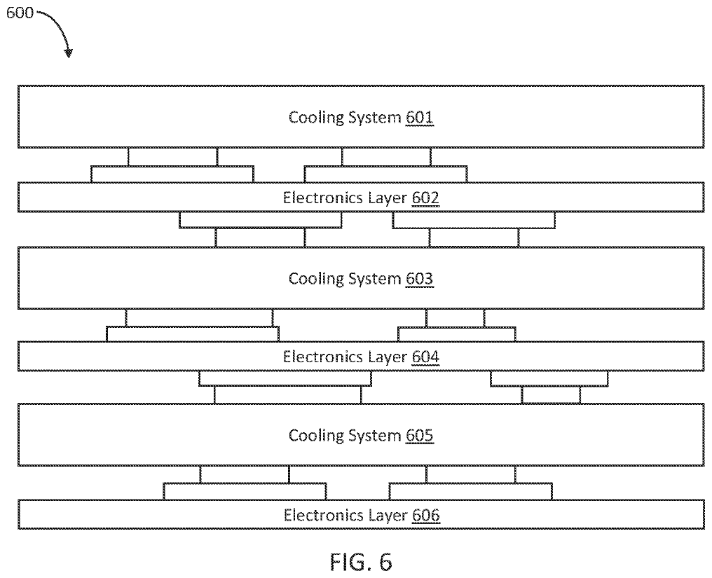

FIG. 6 shows another example embodiment of a vertical cooling solution 600. As shown in FIG. 6, a cooling system 601 can be thermally coupled on a single side to an electronics layer 602. The electronics layer 602 can be double-sided and can also be in thermal contact with cooling system 603. The bottom side of the cooling system 603 can be thermally coupled to a top surface of a double-sided electronics layer 604. The bottom side of the electronics layer 604 can be thermally coupled with cooling system 605. The bottom surface of the cooling system 605 can be in thermal communication with a single-sided electronics layer 606.

While FIGS. 4-6 depict coolers disposed on both sides of electronics layers having electronic components disposed on both sides, other configurations are possible. For example, a double-sided electronics layer may only have cooling on one side, for example because the components on the other side produce little enough heat and/or can tolerate sufficiently high temperatures that they can be operated without cooling and/or with the indirect cooling provided by the cooling system on the opposite side of the electronics layer. In some embodiments, a single-sided electronics layer can have cooling disposed on both sides. Such a configuration may be desirable, for example, if the components in the electronics layer generate an especially large amount of heat or to act as a heat shield to protect more sensitive components in other layers of a stack.

In some embodiments, the electronics layers may comprise a PCB with components disposed thereon. However, other configurations are possible. For example, an electronics layer can be a SoW layer, as discussed above. The SoW layer may have a plurality of IC dies disposed in close proximity to one another. For example, an SoW layer may be prepared from a 300 mm wafer and may have a plurality of IC dies (e.g., an array of 4 dies, 9 dies, 16 dies, 25 dies, 36 dies, 49 dies, and so forth, or another array of IC dies which may or may not be a square array) disposed therein. While current SoW layers are commonly prepared from 300 mm wafers, the systems, methods, and devices disclosed herein could be applied to larger or smaller wafers, for example 200 mm, 450 mm, etc.

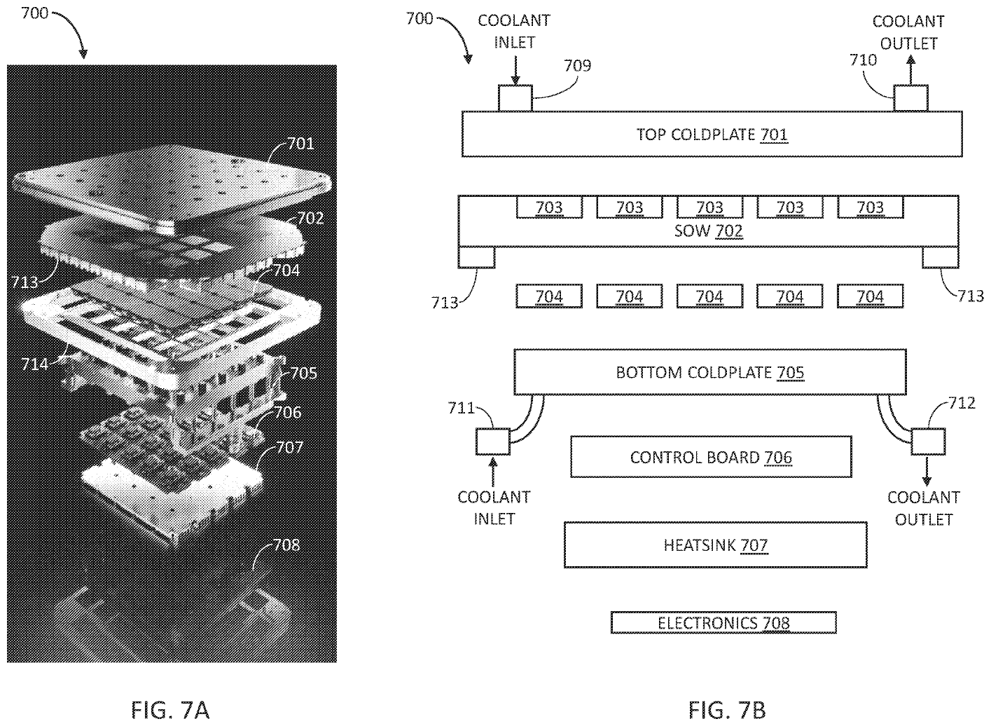

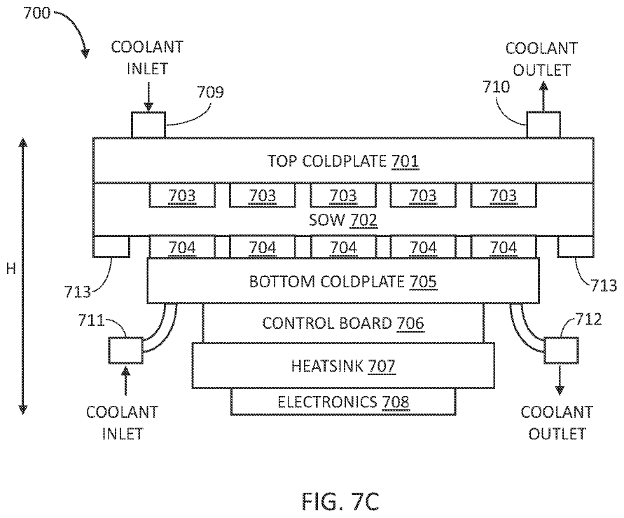

FIGS. 7A, 7B, and 7C show an example computing assembly 700 comprising an SoW layer according to some embodiments. An assembly can include a top cold plate 701 that is thermally coupled to an SoW layer 702. The SoW layer 702 can have a plurality of IC dies 703 disposed therein. Below the IC dies 703, the assembly can have a plurality of power delivery modules 704. Each IC die can have a power delivery module associated therewith and can be electrically connected to the associated power delivery module. A bottom cold plate 705 can be thermally coupled to the power delivery modules. The bottom cold plate 705 can also be thermally coupled to a control board 706, which may be used to provide signaling and control functions to the IC dies. The control board can be in thermal contact with a heatsink 707. Additional electronics 708 can be disposed below the heatsink 707.

The top cold plate 701 can have an inlet 709 for flowing liquid coolant into the top cold plate 701 and an outlet 710 for removing heated liquid coolant from the top cold plate 701. The bottom cold plate can have a cooling inlet 711 for receiving liquid content and a coolant outlet 712 for removing coolant from the bottom cold plate 705. The SoW layer 702 can have communication interfaces 713 disposed at the edges of the SoW layer 702. The communication interfaces 713 can be used to connect the SoW layer 702 to neighboring SoW layers in other assemblies.

FIG. 7C is an assembled view of the exploded assembly shown in FIG. 7B. When assembled, the computing assembly can have a vertical height H of from about 1″ to about 5″, for example about 1″, about 2″, about 3″, about 4″, about 5″ or any value between these values. The number of layers in a vertical stack is not necessarily limited. Thus, the height of a vertical stack is also not necessarily limited.

In some embodiments, rigidity and mechanical strength can be provided by the cooling systems. In some embodiments mechanical reinforcement can alternatively or additionally be provided by support layers, such as the support layer 714 shown in FIG. 7A. The support layer 714 can be a structure made of a rigid material such as a metal, plastic, ceramic, and so forth.

In the foregoing specification, the systems and processes have been described with reference to specific embodiments thereof. It will, however, be evident that various modifications and changes may be made thereto without departing from the broader spirit and scope of the embodiments disclosed herein. The specification and drawings are, accordingly, to be regarded in an illustrative rather than restrictive sense.

Indeed, although the systems and processes have been disclosed in the context of certain embodiments and examples, it will be understood by those skilled in the art that the various embodiments of the systems and processes extend beyond the specifically disclosed embodiments to other alternative embodiments and/or uses of the systems and processes and obvious modifications and equivalents thereof. In addition, while several variations of the embodiments of the systems and processes have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosed systems and processes. Any methods disclosed herein need not be performed in the order recited. Thus, it is intended that the scope of the systems and processes herein disclosed should not be limited by the particular embodiments described above.

It will be appreciated that the systems and methods of the disclosure each have several innovative aspects, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every embodiment.

It will also be appreciated that conditional language used herein, such as, among others, “can,” “could,” “might,” “may,” “for example,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one or more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

What is claimed is:

1. A computing assembly comprising:
a first cooling system;
a first electronics layer having a first surface and a second surface, wherein the first surface is in thermal communication with the first cooling system;
a second cooling system in thermal communication with the second surface of the first electronics layer; and
a second electronics layer having a third surface and a fourth surface, wherein the third surface is in thermal communication with the second cooling system.

2. The computing assembly of claim 1,
wherein the first cooling system is disposed on top of the first electronics layer,
wherein the first electronics layer is disposed on top of the second cooling system, and
wherein the second cooling system is disposed on top of the second electronics layer.

3. The computing assembly of claim 1, further comprising:
a third cooling system; and
a third electronics layer having a fifth surface and sixth surface, wherein the fifth surface is in thermal communication with the third cooling system,
wherein and the fourth surface is in thermal communication with the third cooling system.

4. The computing assembly of claim 1, wherein the first electronics layer is in electrical communication with the second electronics layer.

5. The computing assembly of claim 1, wherein the first electronics layer comprises a system on wafer layer.

6. The computing assembly of claim 1, wherein the first electronics layer comprises an array of integrated circuit dies, and wherein the second electronics layer comprises an array of power delivery modules.

7. The computing assembly of claim 6, wherein each power delivery module of the array of power delivery modules comprises a voltage regulating module.

8. The computing assembly of claim 6, wherein a number of integrated circuit dies in the first electronics layer is equal to a number of power delivery modules in the second electronics layer, and wherein each integrated circuit die is in electrical communication with only one power delivery module.

9. The computing assembly of claim 6, wherein power is delivered vertically from the second electronics layer to the first electronics layer, and wherein the integrated circuit dies of the array of integrated circuit dies are in electronic communication with each other in a plane that is orthogonal to the power delivery.

10. The computing assembly of claim 1, wherein a type of the first cooling system and a type of the second cooling system comprise one or more of a cold plate, a heatsink, and a liquid cooling block.

11. The computing assembly of claim 10, wherein the type of the first cooling system is the same as the type of the second cooling system.

12. The computing assembly of claim 10, wherein the type of the first cooling system is different from the type of the second cooling system.

13. The computing assembly of claim 11, wherein the first cooling system comprises a first liquid cooling block and the second cooling system comprises a second liquid cooling block.

14. The computing assembly of claim 13, wherein the first liquid cooling block is configured to receive a first coolant, and wherein the second liquid cooling block is configured to receive a second coolant.

15. The computing assembly of claim 14, wherein the first coolant and the second coolant comprise one or more of water, propylene glycol, ethylene glycol, or any combination thereof.

16. The computing assembly of claim 14, wherein the first coolant is the same as the second coolant.

17. The computing assembly of claim 14, wherein the first coolant is different from the second coolant.

18. A method for cooling an electronic assembly comprising:
mounting a first cooling layer on top of and in thermal communication with a first electronics layer,
mounting a first electronics layer on top of and in thermal communication with a second cooling system; and
mounting a second cooling system on top of and in thermal communication with a second electronics layer.

19. The method of claim 18, further comprising:
outputting heat vertically from the first electronics layer to the first cooling system;
outputting heat vertically from the first electronics layer to the second cooling system; and
outputting heat vertically from the second electronics layer to the second cooling system.

20. The method of claim 18, further comprising:
providing power vertically from the second electronics layer to the first electronics layer.

21. A computing assembly comprising:
a first cooling system;
a first electronics layer in thermal communication with the first cooling system;
a second cooling system in thermal communication with the first electronics layer;
a second electronics layer in thermal communication with the second cooling system;
a third cooling system in thermal communication with the second electronics layer; and
a third electronics layer in thermal communication with the third cooling system,
wherein the first electronics layer comprises a processing electronics layer, wherein the second electronics layer comprises a power delivery layer, and wherein the third electronics layer comprises a control electronics layer.
